(19) United States
(12) Patent Application Publication
(10) Pub. No.: US 2014/0159205 A1
(43) Pub. Date: Jun. 12, 2014

(54) Low OFF-State Leakage Current Field Effect Transistors

(71) Applicant: Iman Rezanezhad Gatabi, Bryan, TX (US)

(72) Inventor: Iman Rezanezhad Gatabi, Bryan, TX (US)

(21) Appl. No.: 13/709,214

(22) Filed: Dec. 10, 2012

(51) Int. Cl. H01L 29/06

(52) U.S. Cl. CPC H01L 29/0638
USPC 257/547

(57) ABSTRACT

A method is presented to decrease the OFF-state leakage current of the Field Effect Transistors (FETs). The presented method comprises of the placement of dopants underneath or anywhere adjacent to the channel which causes an increase in the band barrier at the source edge of the semiconductor of gate region at the OFF state, providing for less leakage current. Compared with the conventional method of increasing the channel doping to decrease the OFF state leakage current and achieve more scalability, a lower channel doping concentration is needed to achieve the same OFF state leakage current. This provides for less impurity scattering and higher mobility which results in larger ON state currents, higher yields and faster devices.

### CROSS-REFERENCE TO RELATED APPLICATIONS

U.S. Pat. No. 7,005,366, Feb. 16, 2006, Tri-gate devices and methods of fabrication

U.S. Pat. No. 7,268,058, Sep. 11, 2007, Tri-gate transistors and methods to fabricate same

U.S. Pat. No. 7,329,581, Mar. 16, 2005, Field effect transistor (FET) devices and methods of manufacturing FET devices

U.S. Pat. No. 6,403,434, Feb. 9, 2001, Process for manufacturing MOS transistors having elevated source and drain regions and a high-k gate dielectric

U.S. Pat. No. 6,413,802, Oct. 23, 2000, Finfet transistor structures having a double gate channel extending vertically from a substrate and methods of manufacture

U.S. Pat. No. 6,475,869, Feb. 26, 2001, Method of forming a double gate transistor having an epitaxial silicon/germanium channel region

U.S. Pat. No. 6,475,890, Feb. 12, 2001, Fabrication of a field effect transistor with an upside down T-shaped semiconductor pillar in SOI technology

U.S. Pat. No. 6,525,403, Sep. 24, 2001, Semiconductor device having MIS field effect transistors or three-dimensional structure

U.S. Pat. No. 6,635,909, Mar. 19, 2002, Strained fin FETs structure and method

U.S. Pat. No. 6,642,090, Jun. 3, 2002, Fin FET devices from bulk semiconductor and method for forming

U.S. Pat. No. 6,921,700, Jul. 31, 2003, Method of forming a transistor having multiple channels

U.S. Pat. No. 6,995,456, Mar. 12, 2004, High-performance CMOS SOI devices on hybrid crystal-oriented substrates

U.S. Pat. No. 7,329,913, Dec. 27, 2004, Nonplanar transistors with metal gate electrodes

U.S. Pat. No. 7,384,850, Mar. 23, 2005, Methods of forming complementary metal oxide semiconductor (CMOS) transistors having three-dimensional channel regions therein

U.S. Pat. No. 7,442,967, Apr. 20, 2006, Strained channel complementary field-effect transistors

U.S. Pat. No. 8,084,818, Jan. 12, 2006, High mobility tri-gate devices and methods of fabrication

U.S. Pat. No. 4,711,701, Sep. 16, 1986, Self-aligned transistor method

U.S. Pat. No. 5,278,102, Feb. 12, 1993, SOI device and a fabrication process thereof

U.S. Pat. No. 5,804,848, Oct. 31, 1997, Field effect transistor having multiple gate electrodes surrounding the channel region

US20100200923, Apr. 13, 2010, Multiple gate transistor structure and method for fabricating

US20090061572, Oct. 28, 2008, Nonplanar semiconductor device with partially or fully wrapped around gate electrode and methods of fabrication

US20080128797, Nov. 30, 2006, Structure and method for multiple height FinFET devices

US20080111163, Nov. 14, 2006, Field Effect Transistors with a Fin structure

US20070262389, Jul. 25, 2007, Tri-Gate transistors and methods to fabricate same

US20070187682, Aug. 27, 2004, Semiconductor device having fin-type effect transistor

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISC APPENDIX

Not Applicable.

### BACKGROUND OF THE INVENTION

The semiconductor industry has been scaling down transistors for the past decades to meet demands for smaller and more efficient electronic devices. With the transistor scaling trend reaching its practical limits, the search is ongoing to provide alternative structures that can operate in smaller dimensions. These alternative devices should be able to address the so-called “short-channel effects” associated with nano-scale devices to make the future transistor scaling trend feasible. One of the main issues preventing this trend is the increased OFF-state leakage current at short channel lengths. As a result, the device fails to switch OFF properly as the channel length gets very short. Thus, it is exceedingly important to achieve short channel devices with lower OFF-state leakage currents.

In addition to making further transistor scaling feasible, low OFF-state leakage current devices provide for lower power dissipations. For both short and long channel devices, it is critically important to reduce the OFF state power dissipation to achieve energy efficient electronics. The method currently used to decrease the OFF state leakage current is increasing the doping concentration of the channel. However this improves the OFF state leakage current, it degrades the channel mobility due to higher impurity scattering, resulting in a low ON state current. Therefore, a method needs to be implemented to decrease the OFF state leakage while keeping the ON current large, resulting in a large ON to OFF current ratio.

### BRIEF SUMMARY OF THE INVENTION

A method is provided to decrease the OFF state leakage current of Field Effect Transistors (FETs) while providing a large ON to OFF current ratio. Dopants are placed in the proximity of the carrier path at the ON state to increase the energy band barrier at the source edge of the gate region of the semiconductor at the OFF state. One example embodiment is the incorporation of a semiconductor layer underneath or anywhere adjacent to the channel. The incorporation of this layer increases the OFF state energy barrier at the source edge of the semiconductor of the gate region, reducing the carrier injection from the source and providing for a lower leakage current. The lower leakage current achieved by this technique allows for scaling down the channel length of nano-FETs which results in faster devices and higher yields. The provided method can be implemented in any kind of FETs such as Bulk-MOSFETs, FinFETs, SOI-MOSFETs, strained FETs and MultiGate FETs to reduce the leakage current. The same effect can be obtained by forming a channel with graded doping where the peak doping concentration is placed away from the channel and in its proximity.

### BRIEF DESCRIPTION OF THE SEVERAL VIEWS OF THE DRAWING

FIG. 1 illustrates the implementation of the proposed technique to decrease the OFF state leakage current of a basic n-type SOI-MOSFET. In FIG. 1A, a basic n-channel SOI-MOSFET is shown and in FIG. 1B, the higher doped p+ layer is incorporated underneath the channel to decrease the OFF state leakage current.

FIG. 2 compares the conduction band diagrams along the channel for the structures shown in FIG. 1 demonstrating that the barrier at the source edge is increased as a result of incorporated p+ layer. Here, the implemented semiconductor was silicon, n+ doping concentrations at drain and source regions were 3e20 cm⁻³, the p-type regiondoping concentration was 1e17 cm ³, the p+ doping concentration of incorporated layer in FIG. 1B was 5e18 cm⁻³, 2 nm of SiO₂ is used as the gate oxide, the thicknesses of p and p+ layers were 10 nm and the drain bias was 2V.

FIG. 3 compares the I_{d}-V_{g} characteristics of the structures shown in FIG. 1 which demonstrates that the OFF state leakage current is decreased by implementation of the p+ layer. The device specifications were same as what were mentioned in the description of FIG. 2.

FIG. 4 demonstrates that the device of FIG. 1B with a gate length of 40 nm exhibits almost the same OFF state leakage current as the device shown in FIG. 1A with the gate length of 50 nm. Besides the gate lengths, all other specifications (doping concentrations, thicknesses and etc.) were same as what were mentioned in description of FIG. 2.

FIG. 5 compares the conventional technique of increasing the channel doping to decrease the OFF state leakage current with the method of the present invention. The channel lengths of structures shown in FIG. 1 were decreased to 30 nm. For the structure of FIG. 1A, the p-type region doping is increased to 5e18 cm⁻³ and the channel doping of the structure of FIG. 1B is kept unchanged (1e17 cm⁻³) and the p+ doping concentration is increased to 1e19 cm⁻³. While the OFF state leakage currents are approximately the same for both devices, the device with incorporated p+ layer shows an ON state current twice as much as that of the structure without p+ layer at the gate bias of 1V.

FIG. 6 illustrates a possible fabrication process to form the structure of FIG. 1B. Starting with a P+ SOI substrate, the p-type layer is epitaxially grown on top of the wafer. Then the isolation is defined and gate dielectric is deposited. The metal gate is evaporated and patterned and the source and drain regions are implanted in a gate self-aligned process. Finally, the source and drain contacts are evaporated and patterned in a lift-off process.

FIG. 7 shows the implementation of the proposed technique to decrease the OFF state leakage current of a basic p-type SOI-MOSFET. In FIG. 7A, a basic p-channel SOI-MOSFET is shown and in FIG. 7B, the highly doped n+ layer is incorporated underneath the channel to decrease the leakage current.

FIG. 8 shows the implementation of the proposed technique to decrease the OFF state leakage current of a basic n-channel SOI-MOSFET where the highly doped n+ layer is incorporated adjacent to the channel to decrease the OFF state leakage current.

FIG. 9 illustrates the implementation of the proposed technique to decrease the OFF state leakage current of an n-type tri-gate transistor. The incorporated p+ layer is surrounded by the p− doped channel layer as shown in this figure.

### DETAILED DESCRIPTION OF THE INVENTION

Different examples will be described in details with reference to the presented drawings that represent some example embodiments of the present invention. However the technical and structural descriptions presented herein are representative for the purposes of describing the examples, this invention may be embodied in many alternate forms and should not be limited to the example embodiments described herein.

The described examples can be modified in various alternative forms and the thickness of the regions and drawings may be exaggerated for clarity. There is no intention to limit the invention to the particular forms disclosed. However, on the contrary, examples are used to describe the method and to cover some modifications and alternatives within the scope of the invention.

The spatially relative terms used here such as “underneath”, “bellow”, “above” and etc. are for the ease of description and to show the relationship between an element and another one in the figures. If the device in the figure is turned over, elements described as “underneath” or “below” other elements would then be “above” other elements. Therefore, the term “underneath”, for example, can represent an orientation which is below as well as above. If the device is rotated, the spatially relative terms used herein should be interpreted accordingly. The spatially relative terms used herein are in reference to the sketched drawings.

Unless otherwise stated, variations of the shapes of the figures as a result of, for example, manufacturing techniques and tolerances are expected. For instance, a doped rectangle region with a specified doping concentration in illustrations may have rounded or curved features or gradient at its edges rather than an abrupt change from a region to another region. Therefore, the regions illustrated in figures are schematic and their shapes do not necessarily show the actual shape of the fabricated device. Unless otherwise stated, there is no intention to limit the invention to the values (such as dimensions, bias voltages and doping concentrations) used to describe the example embodiments. These values are selected to provide the related characteristics for a better understanding of the invention. Unless otherwise stated, the terms used herein have the same meaning as commonly understood by someone with ordinary skills in the invention field.

The term “channel” is defined as a region where the majority carriers transport in the gate region of Field Effect Transistors at the ON state. For example, in a typical MOSFET and at the ON state, the majority carriers transport within approximately 2 or 3 nm of the gate oxide/semiconductor interface in the semiconductor side. In an n-type AlGaN/GaN High Electron Mobility Transistor (HEMT) for example, the majority carriers travel within approximately 2 or 3 nm of the GaN side of AlGaN/GaN interface at the ON state.

The conventional method to decrease the OFF state leakage current of FETs is increasing the channel doping concentration. However, since the increased channel doping concentration causes more impurity scattering, it degrades the ON state current as well. The main idea of the present invention is placing these dopants a little away from the channel so that they do not affect the ON state current significantly while decreasing the OFF state leakage current. This can either be achieved by incorporation of a doped layer somewhere close to the channel in the gate region, or by using a graded doping concentration in the semiconductor of the gate region where the peak in the doing concentration occurs somewhere away from the channel but close to it.

In an example embodiment of the present invention where the channel is doped, a semiconductor layer that has the same doping type as the channel material is incorporated underneath or anywhere adjacent to the channel. The doping concentration of the incorporated layer should be higher than the doping concentration of the channel so that the OFF state band barrier at the source edge of the semiconductor of gate region is increased, providing for less carrier injection from the source into the channel. For the case of an n-channel FET, the incorporated layer is p+ doped, where p+ stands for the higher doped p-type semiconductor. For the case of a p-channel FET, and the incorporated layer is n+ doped, where n+ stands for the higher doped n-type semiconductor.

In another example embodiment where the channel is undoped, (in some tri-gate transistors and High Electron Mobility Transistors (HEMTs) for example), for the case of n-FETs where the majority carries in the channel are electrons, the doping of the incorporated layer should be p-type and for the case of p-FETs where the majority carriers in the channel are holes, the doping of the incorporated layer should be n-type. The incorporated layer can have different geometrical shapes and it can be placed at any position relative to the channel and in its proximity.

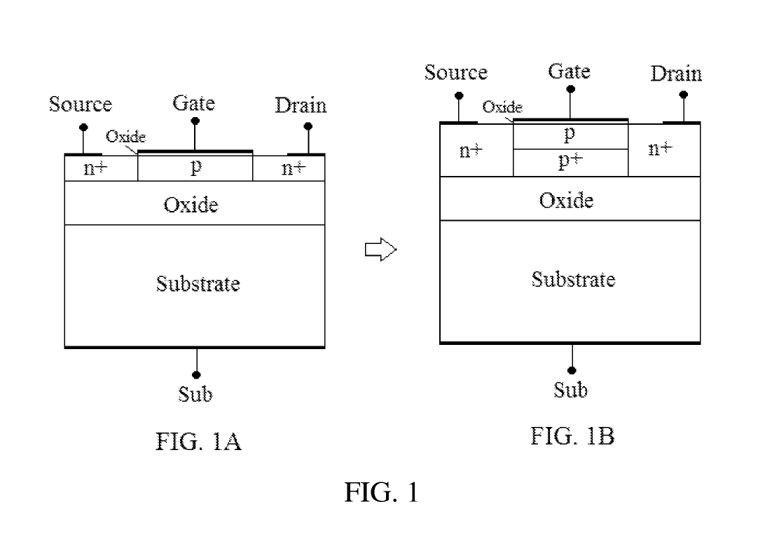

FIG. 1 shows the implementation of the described method in a basic n-channel Semiconductor-On-Insulator (SOI) MOSFET. FIG. 1A illustrates a basic n-channel SOI-MOSFET and FIG. 1B shows the implementation of the proposed technique to reduce the leakage current for the FET of FIG. 1A. In FIG. 1A, at the gate bias of 0V, it is preferred that no majority carriers (electrons in this case) are injected into the gate region from the source so that the device can be switched OFF completely. In reality, this is not the case and there are always some electrons injected into the gate region at the zero gate bias which contribute to the OFF state leakage current. As the gate length gets shorter, the barrier height at the source side of the channel is decreased as a result of drain bias, a process that is called Drain Induced Barrier Lowering (DIBL). As a result, more majority carriers are injected into the channel from the source at the OFF state in shorter channel devices. Therefore, the OFF state leakage current is increased and even in very short channel devices, the device fails to switch OFF properly.

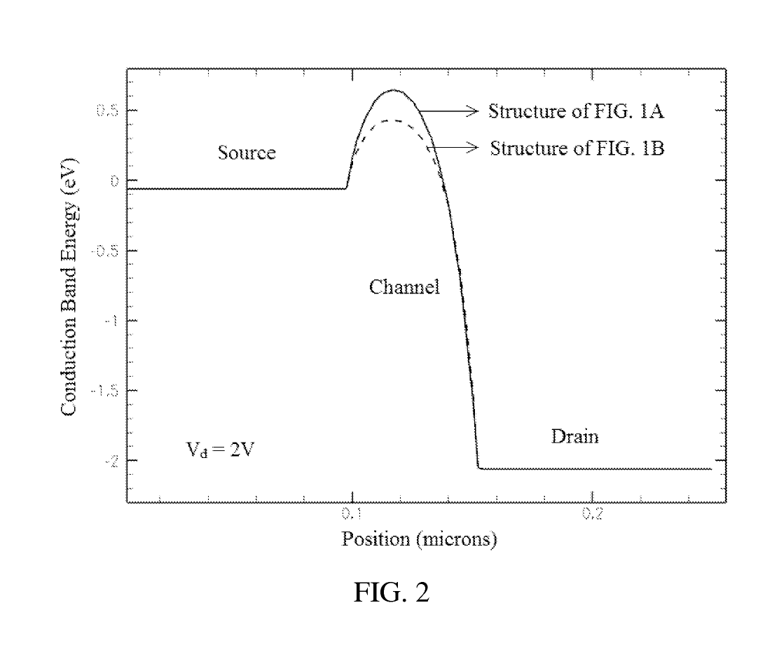

In FIG. 1B, a higher concentration p-doped layer is added underneath the channel which is denoted by p+. Incorporation of this p+ layer underneath the channel causes an increase in OFF-state conduction band barrier at the source edge of the p-type region. Thereforeless electrons are injected from the source into the channel, providing for a lower leakage current. This is demonstrated in FIG. 2, where it shows the simulated OFF state conduction band profile of structures shown in FIG. 1A and FIG. 1B along the channel. In this simulation, the implemented semiconductor was silicon, n+ doping concentrations at drain and source regions were 3e20 cm ³, the p-type region doping concentration was 1e17 cm⁻³, the p+ doping concentration of incorporated layer in FIG. 1B was 5e18 cm⁻³, 2 nm of SiO₂ is used as the gate oxide, the thicknesses of p and p+ layers were 10 nm and the drain voltage was 2V. As illustrated in FIG. 2, the conduction band barrier at the source edge of the p-type region is higher for the structure of FIG. 1.B, providing for less electron injection from the source at the OFF state.

The proximity of the incorporated higher doped layer to the channel is important to achieve a better I_{ON}/I_{OFF} ratio. No significant improvement in I_{ON}/I_{OFF} ratio is achieved if the higher doped layer is placed very far from the channel.

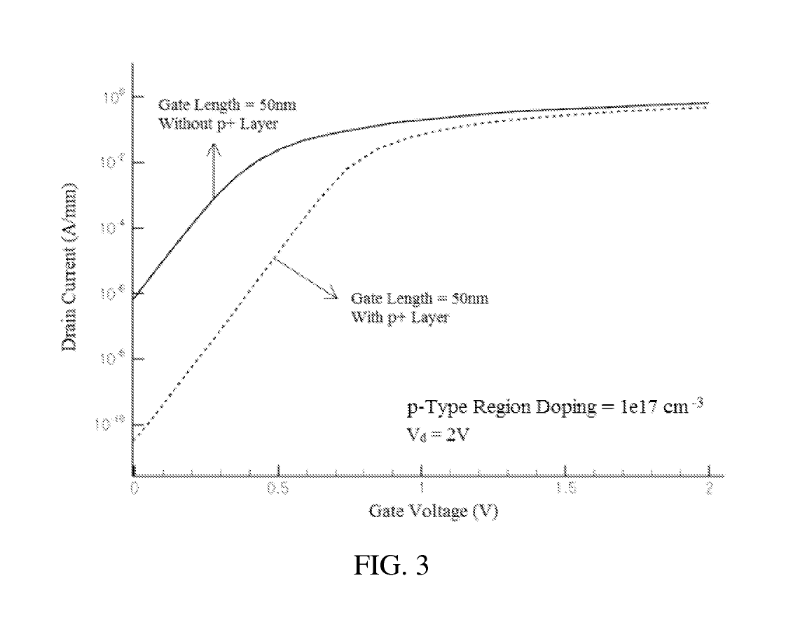

FIG. 3 illustrates the simulated drain current-gate voltage (I_{d}-V_{g}) characteristics of the structures shown in FIG. 1A and FIG. 1B with the specifications used for the simulation of FIG. 2 at a drain bias of 2V. As shown in this figure, the OFF state leakage current is approximately 4 orders of magnitude decreased by incorporation of the p+ layer.

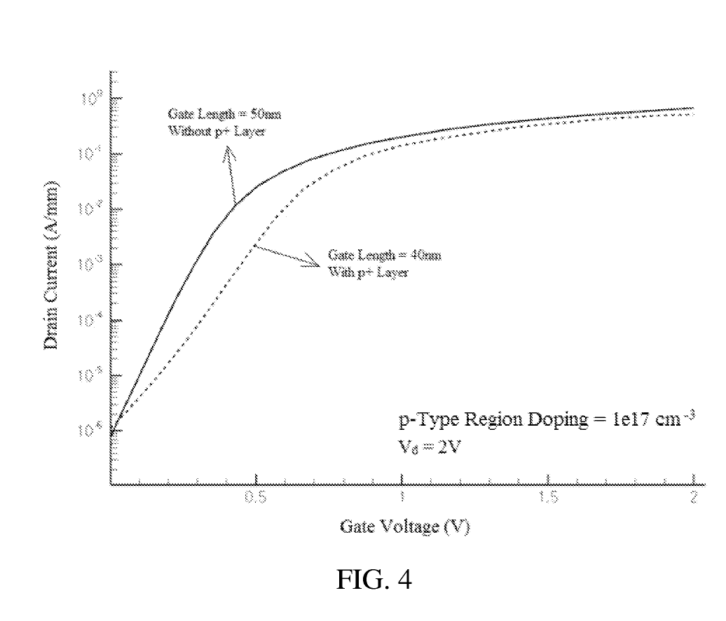

FIG. 4 demonstrates that the structure of FIG. 1B with the gate length of 40 nm has approximately the same I_{OFF} as the structure of FIG. 1A with the gate length of 50 nm. All other specifications (doping concentrations, thicknesses and etc.) are same as what were used for the simulation of FIG. 2. Therefore more device scalability can be achieved by incorporation of the p+ layer.

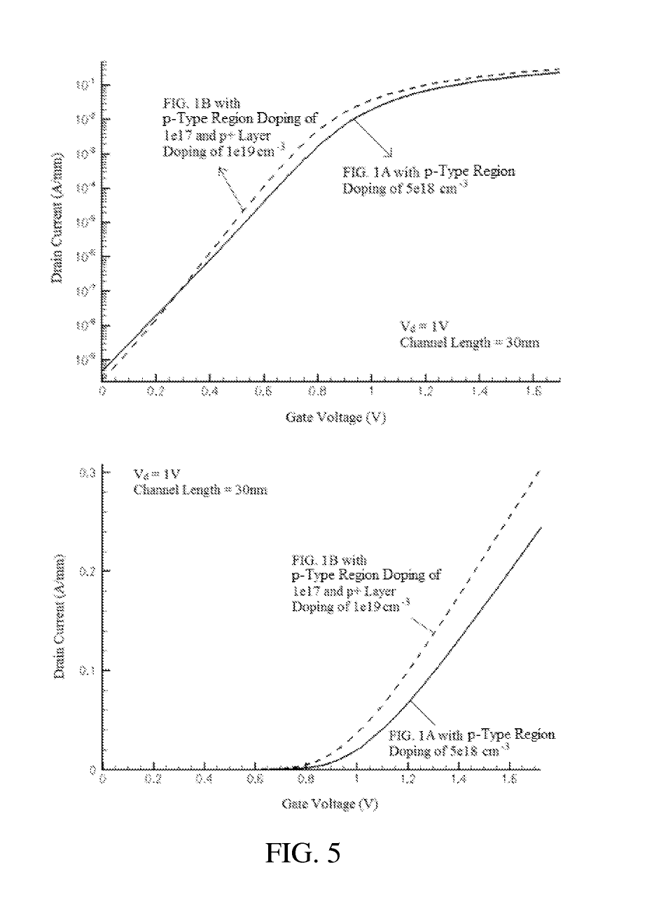

One way used in semiconductor industry to decrease the OFF state leakage current and achieve more scalability is to increase the channel doping. However, increasing the channel doping degrades the mobility due to the impurity scattering which results in lower ON state currents and slower devices. FIG. 5 compares this conventional method to decrease the OFF state leakage current with the proposed method of incorporation of higher-doped layer underneath the channel where the gate length is decreased to 30 nm. The dashed line shows the I_{d}-V_{g} of FIG. 1A with the increased p-type region doping concentration of 5e18 cm⁻³ and the solid line illustrates the I_{d}-V_{g} of FIG. 1B with the p-type region doping concentration of 1e17 cm ⁻³ and the incorporated p+ layer doping concentration of 1e19 cm⁻³. All other specifications are same as what were used in the simulation of FIG. 2. As illustrated in FIG. 5, the doping concentrations are set to achieve approximately the same OFF state leakage current for both devices, however, the ON state current of the device with incorporated p+ layer (dashed line) is twice as much as that of the device without p+ layer at the gate bias of 1V. This is due to the higher channel mobility in the device with incorporated p+ layer. It implies that to achieve a same ON state current, the required device width for the device with incorporated p+ layer is half of that of the device without p+ layer, meaning an increase in yield by implementation of the proposed technique. This ON-state current can be further improved by optimization of the doping concentrations and other device parameters. Moreover, the device with incorporated p+ layer has a better sub-threshold slope as shown in this figure.

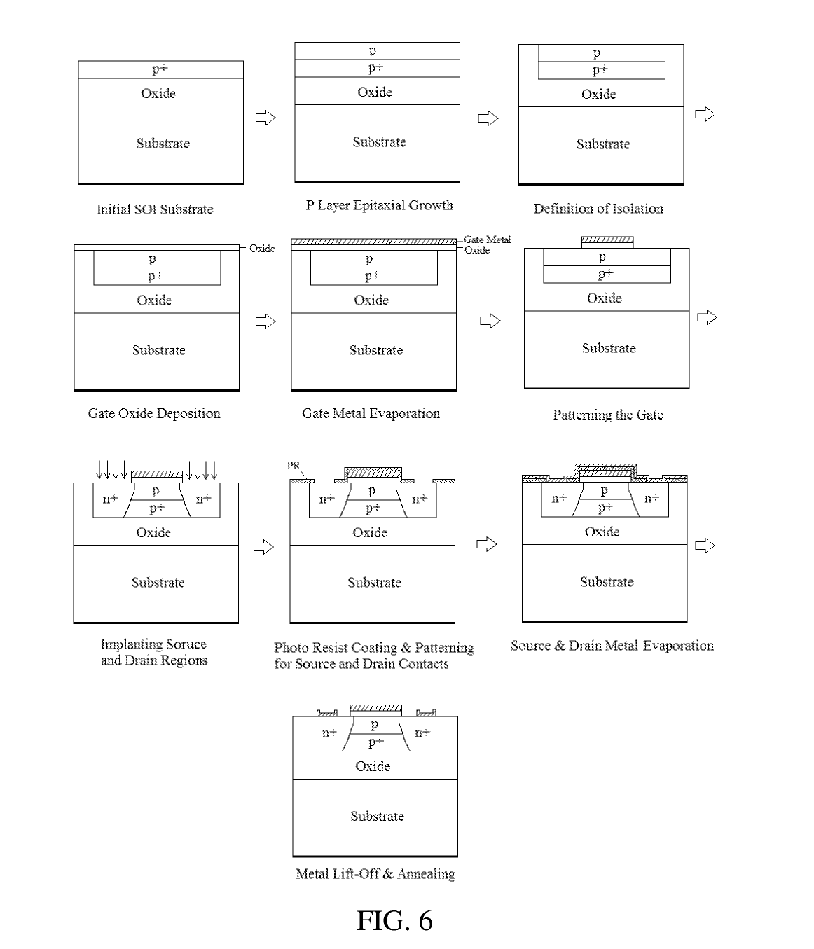

FIG. 6 shows a possible process for fabrication of the structure shown in FIG. 1B. Starting with a P+ SOI substrate, the p-type layer is epitaxially grown on top of the wafer. Then the isolation is defined and gate dielectric is deposited. The metal gate is evaporated and patterned and the source and drain regions are implanted in a gate self-aligned process. Finally, the source and drain contacts are evaporated and patterned in a lift-off process.

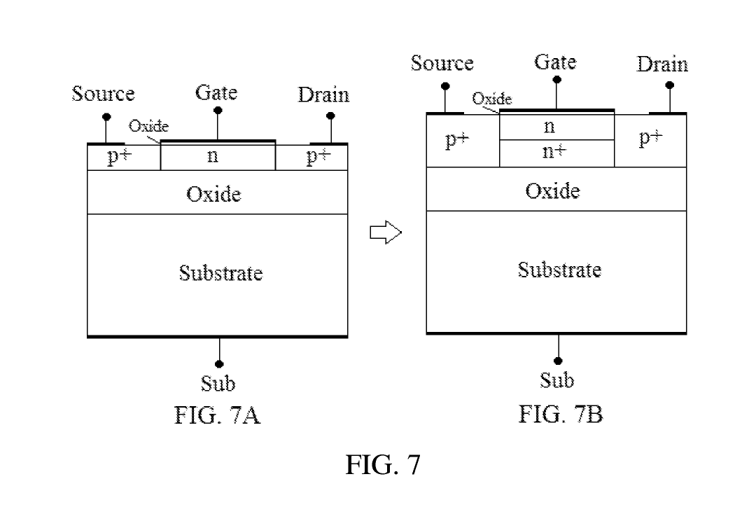

In previous descriptions, the implementation of the technique in a simple n-channel SOI transistor was discussed. However, in other FETs such as more advanced MOSFETs (with spacer, LDD, High-K gate dielectrics and etc . . . ), FinFETs, multi-gate MOSFETs, HEMTs, strained channel MOSFETs and FinFETs (either uniaxial or biaxial strained FETs), the same technique can be applied to decrease the OFF state leakage current and achieve more scalability. FIG. 7 illustrates another example embodiment of the present invention to improve the OFF state leakage current of a p-channel SOI MOSFET where an n+ layer is incorporated underneath the channel.

In the case of devices with intrinsic (undoped) channels, if the device is n-MOS where electrons are majority carriers, the doping type of the incorporated layer should be p-type. If the device is p-MOS with intrinsic channel where holes are majority carriers, the doping type of the incorporated layer should be n-type.

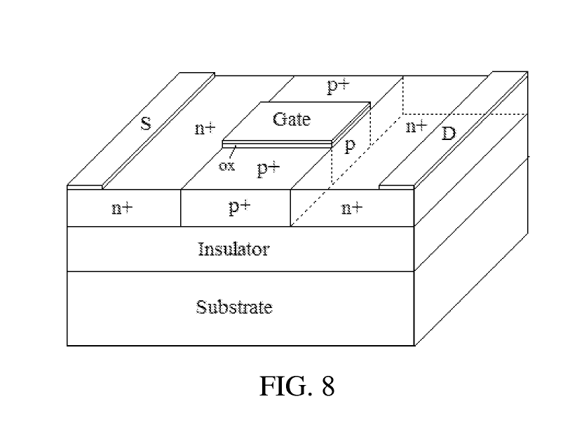

The incorporated layer can also be placed adjacent to the channel as illustrated in FIG. 8 (instead of underneath the channel). In this case, the channel width (the distance between two p+ layers in FIG. 8) should be short in order for the conduction band at the middle of the channel to be affected by the higher doped incorporated regions at the OFF state. If the channel width is not short enough, no considerable reduction in the OFF state leakage current is resulted. In order to achieve larger currents with this structure, the arrays of p and p+ doped regions can be realized along the width of the channel with the gate metal on top of the p regions.

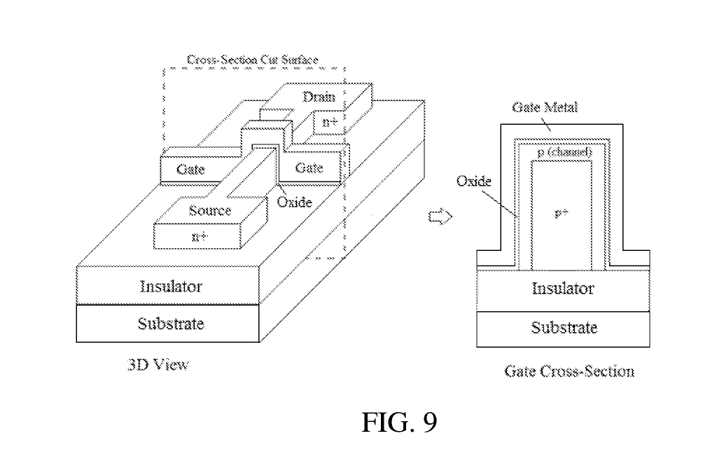

In previous examples, the incorporated highly doped layer was placed underneath or anywhere adjacent to the channel. In general, the highly doped incorporated layer can be placed in different directions relative to the channel and it can have different geometrical shapes. FIG. 9 illustrates the application of this invention in tri-gate transistors where the gate cross-section of an example embodiment is illustrated. As shown in this figure, the channel surrounds the higher-doped p+ region.

A possible fabrication process to apply the method of the present invention to decrease the OFF-state leakage current of tri-gate transistors is the fabrication of the structure shown in FIG. 3D of U.S. Pat. No. 7,268,058B2 where the doping concentration of the region 307 is equal to the desired doping of higher doped region which will be surrounded by the channel. The channel semiconductor can then be grown on top surface and sidewalls of the region 307 of FIG. 3F of the said patent through a selective epitaxy process or any other well-known growth process. The rest of the process is same as what is described in the mentioned patent.

Another possible fabrication process to apply the method of the present invention to decrease the OFF-state leakage current of tri-gate transistors is the fabrication of the structure illustrated in FIG. 5D of U.S. Pat. No. 7,005,366B2 where the doping concentration of the Fins is equal to the desired doping of higher doped region which will be surrounded by the channel. The channel semiconductor can then be grown on top and sidewalls of the Fins through a selective epitaxy process or any other well-known growth process. The rest of the process is same as what is described in the said patent.

Another example embodiment of the present invention can be fabricated by growing the channel semiconductor (through selective epitaxy or any other well-known growth process) on top and sidewalls of semiconductor body 702 of FIG. 7A of U.S. Pat. No. 7,005,366B2 before the formation of the gate dielectric. The rest of the process is same as what is described in the mentioned patent.

1- A method of decreasing the OFF state leakage current of Field Effect Transistors (FETs) with doped channels, said method comprising of incorporation of a semiconductor layer with the same doping type as the channel semiconductor and a doping concentration higher than the channel doping; wherein the higher doped layer that can have different geometrical shapes is incorporated underneath or anywhere adjacent to the channel.

2- A method of decreasing the OFF state leakage current of n-type Field Effect Transistors (FETs) with undoped channels, said method comprising of incorporation of a p-doped semiconductor layer that can have different geometrical shapes underneath or anywhere adjacent to the channel.

3- A method of decreasing the OFF state leakage current of p-type Field Effect Transistors (FETs) with undoped channels, said method comprising of an n-doped semiconductor layer that can have different geometrical shapes is incorporated underneath or anywhere adjacent to the channel.

4- A method of decreasing the OFF state leakage current of Field Effect Transistors (FETs), said method comprising of placing dopants in the gate region of the semiconductor and away from the majority carriers pass at the ON state (channel), wherein the said dopants are n-type in p-FETs and p-type in n-FETs.

5- A Field Effect Transistor (FET) with graded doping in the semiconductor at the gate region, wherein the peak doing concentration is placed away from the channel and in its proximity.

6- The FETs of the first five claims, wherein the FETs are Semiconductor-On-Insulator (SOI) MOSFETs.

7- The FETs of the first five claims, wherein the FETs are Bulk MOSFETs.

8- The FETs of the first five claims, wherein the FETs are Multi-Gate MOSFETs.

9- The FETs of the first five claims, wherein the FETs are FinFETs.

10- The FETs of the first five claims, wherein the FETs are strained MOSFETs.

11- The FETs of the first five claims, wherein the FETs are High Electron Mobility Transistors.
